(19) United States
(12) Patent Application Publication
(10) Pub. No.: US 2008/0135832 A1
(43) Pub. Date: Jun. 12, 2008

(54) Apparatus And Method For Control Of Tunneling In A Small-Scale Electronic Structure

(76) Inventor: Shye Shapira, Kiryat-Tivon (IL)

Correspondence Address: Martin D. Moynihan;PRTSI, P.O. Box 16446, Arlington, VA, 22215, US

(21) Appl. No.: 11/795,266

(22) PCT Filed: Jan. 18, 2006
(86) PCT No.: PCT/IL06/00077

§ 371 Date: Jul. 13, 2007

Related U.S. Application Data
(60) Provisional application No. 60/644,001, filed on Jan. 18, 2005.

(51) Int. Cl. H01L 29/06

(52) U.S. Cl. 257/27; 257/E29.005

(57) ABSTRACT

A microelectronic structure comprising a channel dimensioned such that tunneling is a significant transport mode for charge carriers. The charge carriers have a coherence length depending on the channel material and the carrier type and a wavelength. A potential varying spatially along the length of the channel is applied, the potential having a variation scale or period which is below the wavelength of the charge carriers in the first substance. The channel is typically shorter than the coherence length, which is what causes the tunneling. The potential thereby influences tunneling of the charge carriers through the channel, and can be used to overcome leakage or off current problems due to tunneling that start to appear at these small scales. A very large scale integration circuit containing such a structure is also described.

### FIELD AND BACKGROUND OF THE INVENTION

The present invention relates to apparatus and a method for controlling or influencing tunneling in a small-scale electronic structure, and more particularly but not exclusively for reduction of tunneling related off current in a transistor. The invention further relates to a gate or channel construction suitable for the same.

The present embodiments relate in particular to Insulated Gate Field Effect Transistor (IGFET) design. More specifically, consideration is given to IGFETS with very short channel length where a considerable portion of the leakage currents in their “off state” is due to quantum tunneling. The present embodiments are however more generally applicable to any cases in which tunneling by charge carriers requires to be influenced.

In the following the common term MOSFET (Metal Oxide Semiconductor Field Effect Transistor) is used to include IGFETS in general.

The size of the MOSFET in very large scale integration has been steadily reduced over several decades, generally following Moore's law, halving its critical dimension every 18 months.

Referring now to FIG. 1, and one of the main obstacles in continuing this trend is the increase in the MOSFET off currents (the current between the source and drain when the MOSFET is in the off state). FIG. 1 shows a MOSFET transistor 10 having a drain connection 12, a source connection 14 and a gate connection 16. In normal use the gate connection modulates passage of current between the source and drain. However as the device gets smaller and smaller, the current flowing across the channel when the transistor 10 is in the off state, indicated by arrow 18, increases. The current in the off state is hereinafter referred to as the off current since it continues to flow in the off state.

Reference is now made to FIG. 2, which is a typical energy diagram of the MOSFET with a voltage bias across the source 14 and drain 12 but in the “off” state since the gate is at zero volts. The graph shows energy against channel length, and curve 20 indicates the conduction band edge. For a channel length larger than 10 nm the majority part of the current consists of carriers thermally excited to energies higher than the barrier. A negligible part of the current may come from tunneling of charge carriers with energies on the order of the band edge.

For channel lengths smaller than 10 nm the dominant contribution to the “off” current is from tunneling currents formed by carriers, at energies lower than the barrier, that manage to tunnel through the barrier. The main conduction mechanism is now quantum tunneling and not thermal excitation. Tunneling can be suppressed by raising the energy barrier, that is increasing the voltage on the gate, however the maximum height of the barrier is limited by the order of the operating voltage, Vdd, of the technology.

The source drain current in this case is proportional to

exp(−q*V_{b}/K_{b}T)

where q is the charge of the electron, Vb is the height of the surface potential barrier T, the temperature and Kb the Boltzmann constant. It is more common to present the dependence of the source drain current Ids as a function of the potential on the gate and the threshold voltage:

I_{ds}αexp(−q*(V_{g}−Vₜ/mK_{b}T))¹

where q is the electron charge, Vg is the gate voltage, Vt is the threshold voltage of the transistor
and

δV_{g}/δV_{b}=m>1

In the above equation, m is a scalar larger than 1 indicating that you that you cannot change the barrier in the channel by the gate voltage with full efficiency. In other words the potential in the channel will always change slower than the potential in the gate.

Standard CMOS technology limits the source drain current by a large surface potential barrier in the channel with respect to the source and drain, thus forming an energy barrier that charge carriers need to overcome. Most of the current is driven by carriers which are thermally excited and therefore able to overcome the energy barrier. The result is a density gradient and the “off” current is typically diffusion dominated.

When the channel length is sufficiently short, around 10 nm, carrier tunneling between the source and the drain becomes significant, increasing the off current dramatically. This tunneling current, which increases exponentially with reduced channel length, severely increases the MOSFET off currents.

The source drain current is now proportional to

exp(−l*\sqrt{2mₑ(E−V_{b})/h})

where l is the barrier length, mₑ is the electron effective mass, E the electron energy, and Vb the potential barrier formed by the conduction band edge in the channel in the off state. The same would of course apply to holes in a pMOSFET where the conduction band edge is replaced by the valence band edge and the electron effective mass is replaced by the hole effective mass.

As the power supply voltage decreases with scaling down of MOSFET dimensions, the surface potential barrier height, Vb, in the channel is reduced, resulting in an increased off current. Various device design schemes are implemented to mitigate the barrier height reduction. Some solutions focus on changing the geometry by using multiple gates etc to render the potential barrier in the channel closer to the gate potential. However these procedures can result in a voltage barrier at most with the height of Vdd, the maximum voltage allowed by the technology.

What is needed in the art is a technique to further reduce the off current, so that tunneling ceases to be a barrier to the further miniaturization of the transistor, and so that the dictates of Moore's law can continue to be followed to the final physical limits of semiconductor structures.

### SUMMARY OF THE INVENTION

According to one aspect of the present invention there is provided a microelectronic structure comprising a channel of a first substance, the channel being dimensioned such that tunneling is a significant transport mode for charge carriers, in the off state the charge carriers having a wavelength, the channel having a length and being located within a potential varying spatially along the length, the potential having a variation scale below the wavelength of the charge carriers in the first substance, the potential thereby being able to influence tunneling of the charge carriers through the channel.

According to a second aspect of the present invention there is provided a method of controlling tunneling comprising:

providing a channel for transport of charge carriers, the channel being of a scale such that tunneling is a significant transport mode in the off state therein, the charge carriers having a wavelength within the channel; and

applying a potential varying spatially along the channel, the varying having a feature scale being less than the wavelength.

According to a third aspect of the present invention there is provided a MOSFET comprising: a channel of a first substance, the channel being dimensioned such that tunneling is a significant transport mode in the off state for charge carriers, the charge carriers having a wavelength, the channel having a length and being located within a potential varying spatially along the length, the potential having a variation scale below the wavelength of the charge carriers in the first substance, the potential thereby being able to influence tunneling of the charge carriers through the channel.

According to a fourth aspect of the present invention there is provided the use of a potential about a channel for charge carriers, the channel being of a scale susceptible to tunneling by the charge carriers, the carriers having a wavelength within the channel, the potential being a periodic potential having a wavelength less than the wavelength, the use being to influence tunneling within the channel by modifying the potential.

According to a fifth aspect of the present invention there is provided an integrated circuit including a device providing a potential about a channel for charge carriers, the channel being of a scale susceptible to tunneling by the the charge carriers, the carriers having a wavelength within the channel, the potential being a periodic potential having a wavelength less than the the the carrier wavelength, to the device allowing influencing of tunneling within the the channel by modifying the the potential.

Unless otherwise defined, all technical and scientific terms used herein have the same meaning as commonly understood by one of ordinary skill in the art to which this invention belongs. The materials, methods, and examples provided herein are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified diagram showing the source drain off current in a transistor;

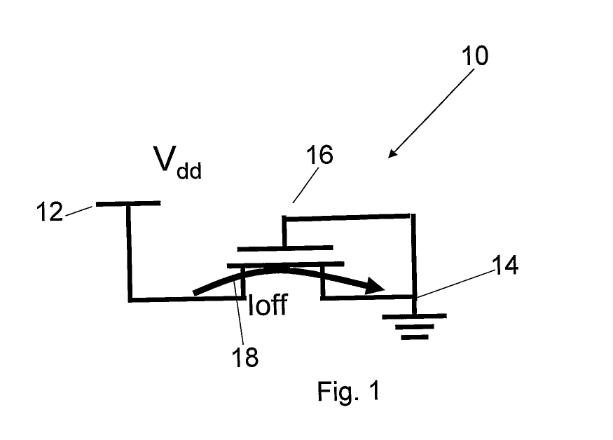

FIG. 2 is a simplified graph illustrating energy barrier levels at a typical MOSFET channel;

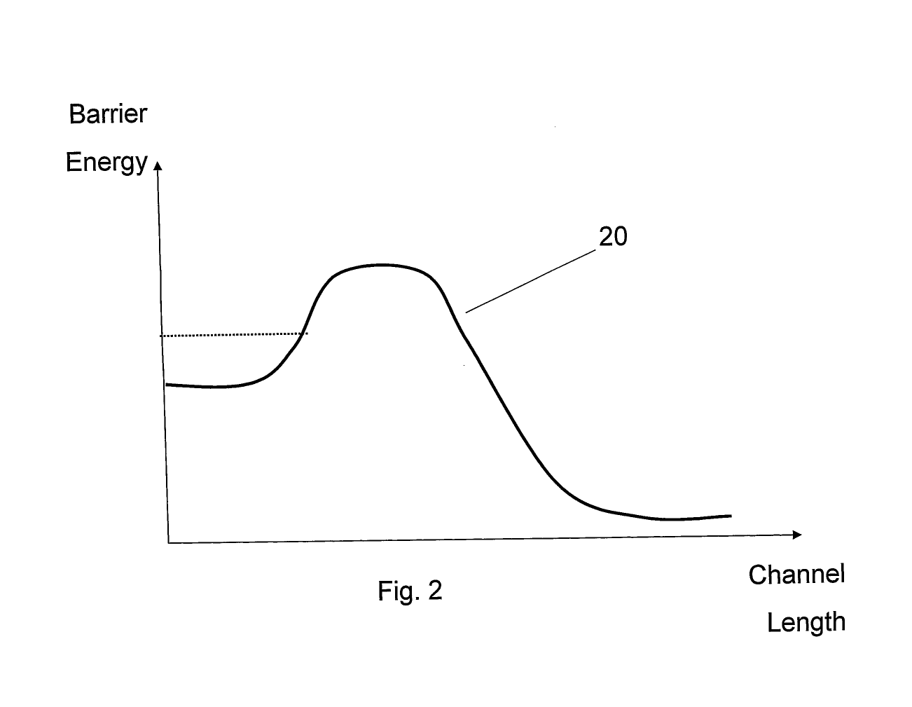

FIG. 3 is a simplified diagram showing the modified energy barrier according to a preferred embodiment of present invention and illustrating how reflections are induced to bring about interference.

FIG. 4 is a simplified schematic diagram, according to a preferred embodiment of the present invention illustrating a semiconductor structure for control of tunneling according to a first preferred embodiment of the present invention.

FIG. 5 is a simplified schematic diagram, according to a preferred embodiment of the present invention illustrating a second semiconductor structure for control of tunneling according to a second preferred embodiment of the present invention.

FIG. 6 is a simplified schematic diagram showing the connection of a voltage to the layers of the structure of FIG. 5, thereby to bring about a potential for modulation of tunneling.

FIG. 7 is a graph illustrating the use of a non-periodic or semi-periodic potential for control of tunneling according to a preferred embodiment of the present invention.

### DESCRIPTION OF THE PREFERRED EMBODIMENTS

The present embodiments comprise an apparatus and a method for influencing tunneling of charge carriers in a channel passing through an energy barrier such as a MOSFET gate in the off state. The embodiments apply a periodic potential to the channel, the potential having a feature scale which is shorter than the coherence length of the charge carriers in the material of the channel. The periodic features of the potential set up multiple reflectance paths for the tunneling particles and for suitable wavelength, the paths interfere. Thus the current allowed by the tunneling can be influenced. If necessary the tunneling effect can be suppressed, thereby overcoming the limitation that tunneling implies for the minimal size of a transistor.

More specifically, the present embodiments provide a modulation of the potential barrier between the source and drain in a MOSFET. The modulation is at a feature scale shorter than the coherence length of electrons in silicon. In this connection, the reader is referred to Quantum Effects in MOS devices, Andreas Wettstein Thesis for Doktor der technischen Wissenschaften, SWISS FEDERAL INSTITUTE OF TECHNOLOGY. In physics, the coherence length is the propagation distance from a coherent source to a point where a wave maintains a specified degree of coherence. The significance is that interference can exist within a coherence length of the source, but not beyond it. Based on the above citation, the coherence length for electrons in silicon at a temperature of 300K is herein approximated as 20 nm. At such a wavelength the electrons interfere as waves. Such a modulation may suppress tunneling of carriers through the barrier by introducing multiple carrier reflections from sections of the barrier which interfere constructively as Bragg reflectors.

The principles and operation of an apparatus and method according to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

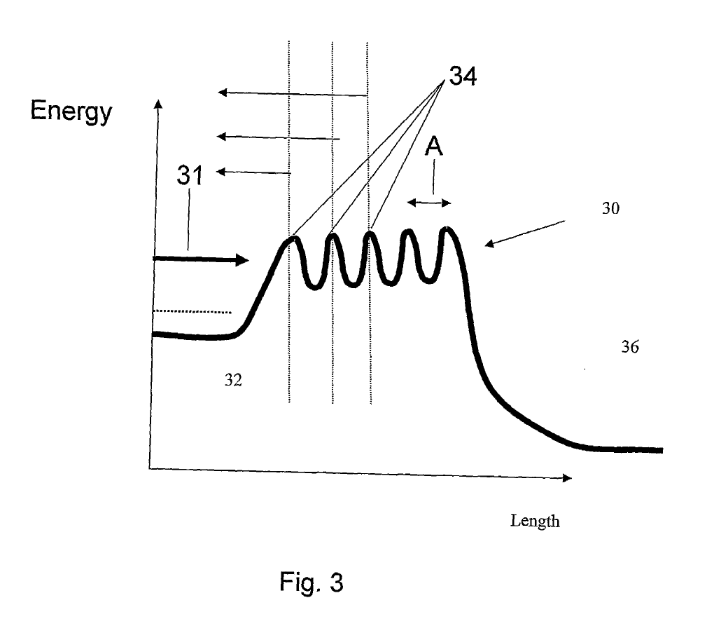

Reference is now made to FIG. 3, which is a graph showing the result of periodic modulation of the barrier as follows: Band edge 30 is modulated with a period, A. A is selected to be an integer multiple of half the electronic wavelength A=N*λ/2, N=1, 2, 3 . . . , wherein λ is the electron (or hole) wavelength). Carriers impinging on the barrier from a source at end 32, are reflected in different paths by periodic energy barriers 34, to form separate paths differing by a phase of N*2*π. Thus reflections from the interfaces along the different paths interfere constructively, resulting in a large probability of electrons to be reflected by the barrier back to the source 32, and very little probability for an electron to reach the drain 36. Thus overall charge carrier current to the drain, 36 is reduced.

Preferably, the modulation of the barrier is at a period on the order of half the wavelength. The wavelength may typically be 30 Angstroms for a charge density of 10¹³ carriers/cm². Thus the modulation is of the order of magnitude of an integer multiple of 15 Angstrom. For a carrier density of 10¹² carriers/cm³ the wavelength is 100 Angstrom and the modulation required is of the order of magnitude of an integer multiple of 50 Angstroms.

It is noted that the wavelength is dependent on the carrier density, and it is believed that the ability to influence tunneling as described herein is sensitive to the carrier density. That is to say the successful design of such a transistor depends on providing a channel carrier density that allows for a wavelength at a scale at which it is possible to provide features on the semiconductor to modulate the potential.

It is further noted that charge carriers only behave as waves at below their coherence length. The periodicity of the potential is preferably such that at least two energy peaks are present over the length of the channel. The distance between each energy peak is preferably half a wavelength and each half wavelength should be less than the coherence length.

Thus, in semiconductors, coherences length, being of the order of 10 nanometers at room temperature in typical MOS channels, are well above the wavelength.

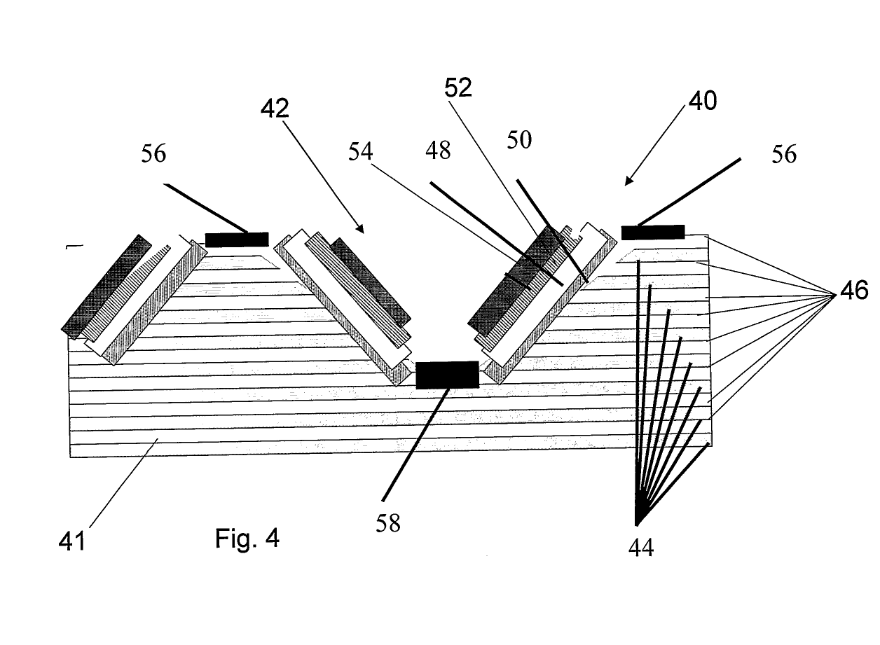

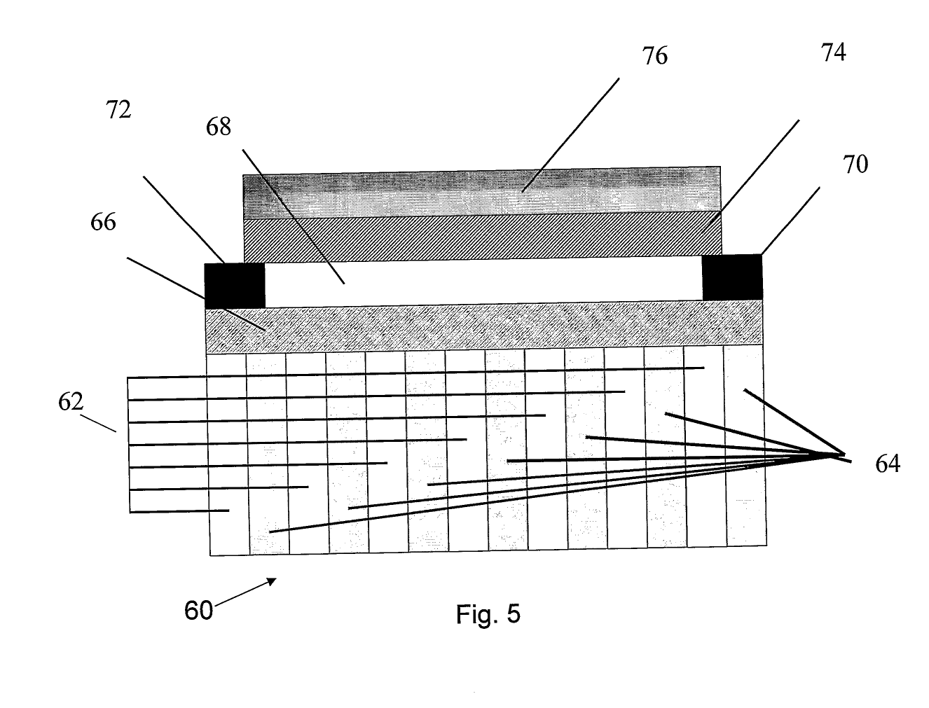

Reference is now made to FIGS. 4 and 5, which show two exemplary ways of providing a MOSFET having a gate that can be modulated using a wavelength of the above order of magnitude.

FIG. 4 is a schematic diagram showing a MOSFET 40 grown in a substrate 41 into which a groove 42 is etched. The groove is etched into the substrate, and the substrate comprises interchanging layers 44 and 46 of two different kinds of semiconductors. The two semiconductors may be for example silicon and silicon-germanium layers.

The groove 42 may be etched. Both wet and dry etching may be suitable.

The silicon and silicon germanium layers 44 and 46 may be grown epitaxially using known techniques and can achieve periods, layer thicknesses on the order of 30 Angstrom or less. Another possible implementation may be to use a substrate with alternating layers produced by implant. The groove may have two sloping sides or edges as shown and in fact FIG. 4 shows separate transistors on each edge.

The layers may be doped so they are conducting and may then be contacted by back contacts so they can be connected to voltage sources and hence tune the height of the modulated voltage barrier. Alternatively if the layers are not connected to a voltage source they may still form a modulated barrier via the stress induced in the silicon channel above them.

The layered structure so formed may be seen as a periodic lattice composed of a silicon germanium superlattice, and forms a back gate for the transistors on the chip, as will now be explained.

Having constructed the groove, the MOSFET channel is preferably constructed therein. Silicon may be deposited, to which are applied standard semiconductor processing steps. Silicon deposition is initially carried out using a method such as metal organic chemical vapor deposition. A silicon channel layer 48 is formed, and the channel layer may if required be preceded by a backgate 50 formed through oxide deposition. The formation of the silicon channel layer is followed by growth or deposition of a gate dielectric layer 52, preferably using dielectric growth or deposition. The gate dielectric layer 52 can be an oxide layer or other material having a high k dielectric.

The dielectric layer is followed by a second layer 54, for example of polysilicon, followed by metal deposition. The metal deposition may use Cobalt Ti Nickel or others, and the deposition may be followed by a silicidation process to leave a conducting CoSi Ti layer 54 or a highly conductive TiSi layer on top of the polysilicon dielectric gate layer 52.

The gate may in one preferred embodiment comprise fully silicided silicon thereby forming a complete metal layer. As described above the method is suitable for channels which are on the order of 10 nm and shorter, in which tunneling becomes a dominant factor in the off current. Contacts 54, source contact, and 56, drain contact, are formed in the standard manner by doping silicidation and the contacts are connected to metal wires at the backend.

The skilled person will appreciate that the transistor that is formed above the groove may be of a different geometry, and an example is given of the Finfet transistor, in which the silicon channel layer is first etched to a narrow strip and then a gate is deposited, such as to wrap the channel from three sides. The groove however remains the same, namely alternating layers of two semiconductors such as Silicon and Silicon Germanium. The Finfet is discussed in FinFET scaling to 10 nm gate length, Bin Yubin yu et al Electron Devices Meeting, 2002. IEDM '02. Digest, International 8-11 Dec. 2002 Page(s):251-254

It is noted that in the example of FIG. 4, the channel experiences gate voltages from one side and modulations from the other side. As mentioned, FIG. 4 shows separate transistors on each groove edge.

In the arrangement of FIG. 4, a periodic potential is achieved by growth over the layered structure into which the groove is cut. The use of grooves in this manner allows manufacture of large numbers of transistors in very large scale integration. As explained, prior to groove formation, layers of at least two different kinds are formed, either by growth or implant. The grooves are formed in the layered structure by wet or dry etch, followed by the growth of the layer which forms the conducting channels. The gate oxide and gate material then follow using standard CMOS processes, as explained above.

Reference is now made to FIG. 5, which is a simplified diagram showing an alternative MOSFET according to a second preferred embodiment of the present invention. The MOSFET of FIG. 5 differs from that of FIG. 4 in that a groove is not provided and the MOSFET is constructed directly on a layered substrate at right angles to the plane of the layers. Substrate 60 comprises two interchanging layers 62 and 64.

On top of the substrate, a backgate insulating layer, 66, is optionally grown. The backgate insulating layer is typically an oxide layer. A channel layer 68 may be grown on top of the backgate insulation layer 66. Source and drain areas 70 and 72 are formed in the standard way. A gate insulation material, 74 is formed on top of the channel layer, and this is followed by gate layer 76.

In MOSFET 60 of FIG. 5, the alternating layers have electron affinities and lattices which mismatch with both each other and the channel. Consequently they induce an alternating potential barrier in the MOSFET channel.

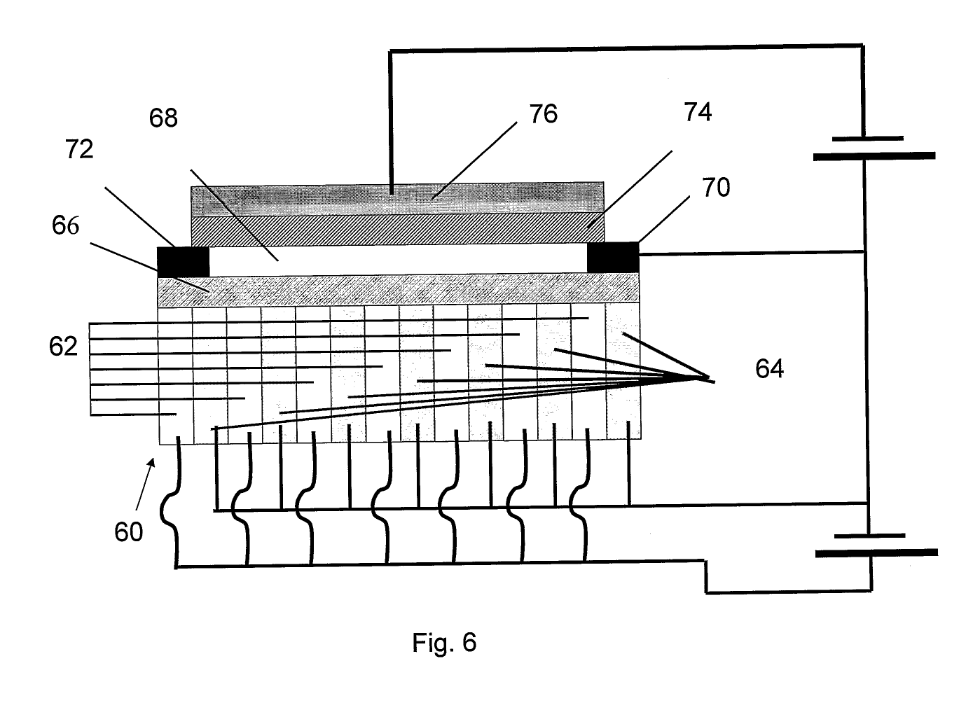

Reference is now made to FIG. 6, which is a simplified diagram showing how the MOSFET 60 of FIG. 5 may be connected to an electrical supply in order to apply a modulation of the kind described above. Parts that are the same as in FIG. 5 are given the same reference numerals and are not referred to again except as necessary for an explanation of the present embodiment. Alternating substrate layers 62 and 64 are preferably connected to different voltage sources, thus forming a periodic potential over the physical length of the channel. In a preferred embodiment the voltages are controllable so that the amplitude of the potential causing the variation may be varied.

In an embodiment, different layers in the modulating gate are connected to different voltage sources and can be placed at a different voltages. The voltages may be associated with the gate so that the magnitude of the modulation can be controlled by the gate. The modulation can thus be applied only when the gate is switched off. Alternatively the modulation may be applied in such a way as to suppress tunneling when the gate is off but to enhance tunneling when the gate is on.

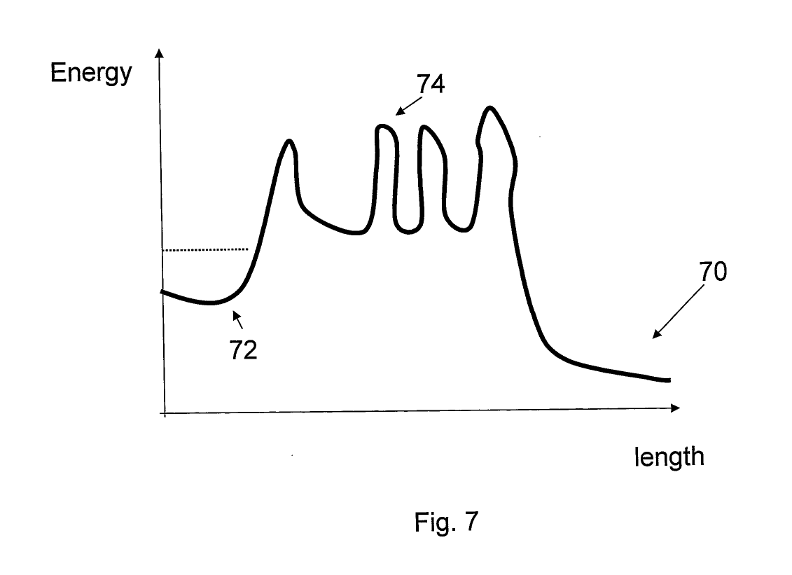

Reference is now made to FIG. 7, which is another graph showing energy against length along the channel. In FIG. 7 the modulation pattern is that of a non periodic potential. It is noted that a non-periodic modulation may also reduce tunneling, as known with localization mechanisms as suggested in Absence of Diffusion in Certain Random Lattices P. W. Anderson Phys. Rev. 109, 1492-1505 (1958).

In FIG. 7, the drain end is 70, the source is 72, and the conduction band edge is 74.

An alternative embodiment may use Carbon Nanotube transistors or organic molecule base transistors. Either of these are likewise gated by a gate inducing a periodic potential in the channel to suppress tunneling.

It is noted that with controllability of the periodic potential, it is possible to modulate the gate between a tunneling suppressing and a tunneling enhancing mode, thus providing the full function of a transistor switch from on to off, and obviating the need for direct use of the gate. That is to say a layered backgate in proximity to a channel may provide a simplified electronic transistor.

A MOSFET according to a preferred embodiment of the present invention uses a gate insulator material which is periodically patterned by variation of thickness, doping or defects to achieve a periodic potential in the channel which suppresses carrier transport in the “off” state. The same MOSFET may optionally allow modulation in different ways in order to provide enhanced transport for an ‘on’ state that either enhances gate activity or replaces the gate activity.

In a further embodiment, in place of epitaxially grown or deposited layers, the gate may be modulated by other material with small dimensions, such as an array of carbon nanotubes. The nanotubes form the periodic potential in the channel.

A vertical transport device may be provided in which a periodic potential is formed in the channel by alternating layers of material.

It is expected that during the life of this patent many relevant devices and systems will be developed and the scope of the terms herein, particularly of the terms MOSFET, and IGFET, is intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents, and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A microelectronic structure designed to operate in two states, a high current conductivity state, and a low current conductivity state, the structure comprising a channel of a first substance, the channel being dimensioned such that, in the low conductivity state, tunneling is a significant transport mode for charge carriers, the charge carriers having a wavelength, the channel having a length and being located within a potential varying spatially along said length, the potential having a variation scale below the wavelength of the charge carriers in said first substance, the potential thereby being able to influence tunneling of said charge carriers through said channel.

2. The microelectronic structure according to claim 1, wherein said potential is a periodic potential in space having a period.

3. The microelectronic structure according to claim 1, wherein:
a) said charge carriers have a coherence length,
b) the length of said channel is less than or in the order of said coherence length, and
c) the wavelength is less than said coherence length.

4. The microelectronic structure according to claim 2, wherein said period is substantially half said charge carrier wavelength.

5. The microelectronic structure according to claim 1, wherein said potential further comprises an amplitude and wherein said amplitude is electronically modifiable, thereby further to influence said tunneling.

6. The microelectronic structure of claim 1, wherein said potential is a non-periodic potential.

7. The microelectronic structure of claim 1, wherein said channel is located between a source and a drain in proximity to a gate layer, thereby to form a field effect transistor with tunneling control.

8. The microelectronic structure of claim 1, wherein said channel is located between a source and a drain, thereby to form a tunneling transistor wherein switching is brought about by modulating said potential.

9. The microelectronic structure of claim 1, wherein said channel is placed in proximity to a substrate of differential layers, said differential layers giving rise to said potential.

10. The microelectronic structure of claim 9, wherein said layers are planar layers at right angles to said length.

11. The microelectronic structure of claim 9, wherein said channel is located in a groove etched within said substrate.

12. The microelectronic structure of claim 11, wherein said groove has two slopes and a separate channel is provided in each slope.

13. The microelectronic structure of claim 12, wherein said substrate has a plurality of grooves, each groove having two slopes and each slope having at least one channel.

14. The microelectronic structure of claim 9, wherein said substrate of differential layers comprises a configuration of carbon nanotubes.

15. The microelectronic structure of claim 1, wherein said channel substantially comprises silicon, wherein said wavelength is substantially 60 angstroms and wherein said variation scale is substantially 30 angstroms.

16. The microelectronic structure of claim 1, wherein said charge carriers have a coherence length, wherein said coherence length is approximately 20 nanometers, and said channel length is ten nanometers or below, thereby rendering tunneling a significant transport mode.

17. A method of controlling tunneling comprising:
providing a channel for transport of charge carriers, said channel being of a scale such that tunneling is a significant transport mode therein, the charge carriers having a wavelength within said channel; and
applying a potential varying spatially along said channel, said varying having a feature scale being less than said wavelength.

18. The method of claim 17, wherein said potential is a periodic potential.

19. The method of claim 18, wherein said feature scale is a wavelength of said periodic potential and wherein said period is substantially half of said length.

20. The method of claim 17, wherein said potential has an amplitude, the method further comprising varying said amplitude to control said tunneling.

21. The method of claim 18, further comprising varying said periodic wavelength to control said tunneling.

22. The method of claim 17, wherein said potential is a non-periodic potential.

23. The method of claim 17, comprising varying said potential between a first, tunneling state allowing tunneling through said channel and a second, tunneling preventing state in which tunneling through said channel is suppressed.

24. A MOSFET comprising: a channel of a first substance, the channel being dimensioned such that tunneling is a significant transport mode for charge carriers, the charge carriers having a wavelength, the channel having a length and being located within a potential varying spatially along said length, the potential having a variation scale below the wavelength of the charge carriers in said first substance, the potential thereby being able to influence tunneling of said charge carriers through said channel.

25. The MOSFET of claim 24, further comprising a potential application structure in proximity to said channel, thereby to apply said potential about said channel.

26. The MOSFET of claim 25, wherein said potential application structure comprises differential features at said variation scale.

27. The MOSFET of claim 26, wherein said differential features comprise differential semiconductor layers.

28. The MOSFET of claim 25, wherein said potential application structure is electronically controllable to set said potential into a first state for suppression of tunneling.

29. The MOSFET of claim 28, wherein said potential application structure is further electronically controllable to set said potential into a second state not suppressing tunneling.

30. The use of a potential about a channel for charge carriers, the channel being of a scale susceptible to tunneling by said charge carriers, the carriers having a wavelength within said channel, the potential being a periodic potential having a wavelength less than said wavelength, the use being to influence tunneling within said channel by modifying said potential.

31. An integrated circuit comprising a plurality of microelectronic structures, each structure designed to operate in two states, a high current conductivity state, and a low current conductivity state, the structure comprising a channel of a first substance, the channel being dimensioned such that in the low conductivity state, tunneling is a significant transport mode for charge carriers, the charge carriers having a wavelength, the channel having a length and being located within a potential varying spatially along said length, the potential having a variation scale below the wavelength of the charge carriers in said first substance, the potential thereby being able to influence tunneling of said charge carriers through said channel.

32. The Integrated circuit of claim 31, wherein said microelectronic structures comprise transistors in very large scale integration.
